(19) United States
(12) Patent Application Publication
(10) Pub. No.: US 2013/0264703 A1
(43) Pub. Date: Oct. 10, 2013

(54) SEMICONDUCTOR PACKAGES AND METHODS FOR MANUFACTURING THE SAME

(71) Applicant: SAMSUNG ELECTRONICS CO., LTD., Suwon-si (KR)

(72) Inventors: Yujung TAE, Hwasung-City (KR); ByoungRim SEO, Hwasung-City (KR); IN WON O, Hwasung-City (KR)

(73) Assignee: SAMSUNG ELECTRONICS CO., LTD., Suwon-si (KR)

(21) Appl. No.: 13/779,722

(22) Filed: Feb. 27, 2013

(30) Foreign Application Priority Data
Apr. 9, 2012 (KR) 10-2012-0036624

(51) Int. Cl. H01L 23/498; H01L 23/48

(52) U.S. Cl. CPC H01L 23/49811; H01L 23/48
USPC 257/737; 257/778

(57) ABSTRACT

A semiconductor package includes a holder covering or encapsulating an edge part of a semiconductor chip. Thus, it may be possible to isolate the edge part on which contaminants may easily exist from a pixel part. As a result, the contaminants from the edge part do not contaminate the pixel part, so that distortion of an image may be prevented.

### CROSS-REFERENCE TO RELATED APPLICATIONS

This U.S. non-provisional patent application claims priority under 35 U.S.C. §119 to Korean Patent Application No. 10-2012-0036624, filed on Apr. 9, 2012, the entirety of which is incorporated by reference herein.

### BACKGROUND

The inventive concept relates to semiconductor devices and, more particularly, to semiconductor packages and method for manufacturing the same.

Image sensors such as a charge coupled device (CCD) sensor or a complementary metal-oxide semiconductor (CMOS) image sensor have been employed in the manufacture of various electronic products, including, for instance, mobile phones, digital cameras, optical mice, security cameras, and biometric devices. As electronic products become smaller and more multi-functional, it is desirable for semiconductor packages with image sensors to have characteristics such as small size/high density, multi-function operation, high speed signal processing, high reliability, low manufacturing costs, and high definition. Research has been conducted for satisfying the above requirements.

### SUMMARY

Embodiments of the inventive concept may provide semiconductor packages capable of substantially reducing the distortion of an image which may be caused by contamination of a pixel part of a semiconductor chip used as an image sensor chip.

Embodiments of the inventive concept may also provide method for manufacturing a semiconductor package capable of preventing distortion of an image which is caused by contamination of a pixel part.

In one aspect, a semiconductor package may include: a package substrate; a semiconductor chip disposed on the package substrate and including a pixel part and an edge part; a holder covering at least a region of the edge part and exposing the pixel part; and a transparent substrate disposed adjacent to the top surface of the holder.

In some embodiments, the holder may include an inner cover part and an upper cover part; the inner cover part may be adjacent to the edge part and may further be inclined with respect to the top surface of the semiconductor chip; and the upper cover part may be connected to a top end of the inner cover part and be arranged adjacent to the transparent substrate.

In other embodiments, the holder may further include an outer cover part connected to the upper cover part and adjacent to the package substrate.

In still other embodiments, the semiconductor package may further include: an adhesive layer disposed between the outer cover part and the package substrate and/or between the inner cover part and the semiconductor chip.

In even other embodiments, an angle between a sidewall of the inner cover part and the top surface of the semiconductor chip adjacent to the pixel part may be greater than about 90 degrees.

In yet other embodiments, the upper cover part may be spaced apart from an end portion of the semiconductor chip to provide a space.

In yet still other embodiments, the semiconductor package may further include: a first adhesive layer filling the space.

In further embodiments, the first adhesive layer may extend between a bottom surface of the inner cover part and the top surface of the semiconductor chip.

In still further embodiments, the semiconductor package may further include: a second adhesive layer disposed between an end portion of the transparent substrate and the upper cover part.

In even further embodiments, the second adhesive layer may cover at least a portion of a sidewall of the transparent substrate and at least a portion of a sidewall of the upper cover part.

In yet further embodiments, a surface roughness of a top surface of the upper cover part may be greater than a surface roughness of a sidewall of the inner cover part.

In yet further embodiments, a width of a lower portion of the inner cover part may be smaller than a width of an upper portion of the inner cover part.

In yet further embodiments, the semiconductor package may further include: a wire connecting the edge part to the package substrate. The holder may cover the wire.

In yet further embodiments, the semiconductor chip may be mounted on the package substrate by a flip-chip bonding method.

In another aspect, a method for manufacturing a semiconductor package may include: mounting a semiconductor chip including a pixel part and an edge part on a package substrate; bonding a holder on the edge part, the holder covering at least a region of the edge part and exposing the pixel part, and the holder having a top surface spaced apart from a top surface of the semiconductor chip; and bonding a transparent substrate on the holder.

In some embodiments, the method may further include: performing a cleaning process after bonding the holder on the edge part.

In other embodiments, bonding the holder on the edge part may include applying a first adhesive layer covering an end portion of the semiconductor chip; locating a bottom surface of the holder on the first adhesive layer; and pressing the holder.

In still other embodiments, bonding the transparent substrate may include: applying a second adhesive layer to a top surface of the holder; locating an edge portion of the transparent substrate on the second adhesive layer; and pressing the transparent substrate.

### BRIEF DESCRIPTION OF THE DRAWINGS

The inventive concept will become more apparent in view of the attached drawings and accompanying detailed description.

FIG. 1 is a plan view illustrating a semiconductor package according to some embodiments of the inventive concept;

FIG. 2A is a cross-sectional view taken along line IT of FIG. 1 to explain a semiconductor package according to a first embodiment of the inventive concept;

FIG. 2B is a perspective view illustrating a holder according to a first embodiment of the inventive concept;

FIGS. 3 to 9 are cross-sectional views illustrating a method for manufacturing a semiconductor package of FIG. 2A;

FIG. 10 is a cross-sectional view taken along line IT of FIG. 1 to explain a semiconductor package according to a second embodiment of the inventive concept;

FIG. 11 is a cross-sectional view taken along line IT of FIG. 1 to explain a semiconductor package according to a third embodiment of the inventive concept;

FIG. 12 is a cross-sectional view taken along line IT of FIG. 1 to explain a semiconductor package according to a fourth embodiment of the inventive concept;

FIG. 13 is a cross-sectional view taken along line I-I′ of FIG. 1 to explain a semiconductor package according to a fifth embodiment of the inventive concept;

FIG. 14 is a cross-sectional view taken along line I-I′ of FIG. 1 to illustrate a semiconductor package according to a sixth embodiment of the inventive concept; and

FIGS. 15 to 19 show examples of multimedia devices applied with semiconductor packages for photographing an image according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

### First Embodiment

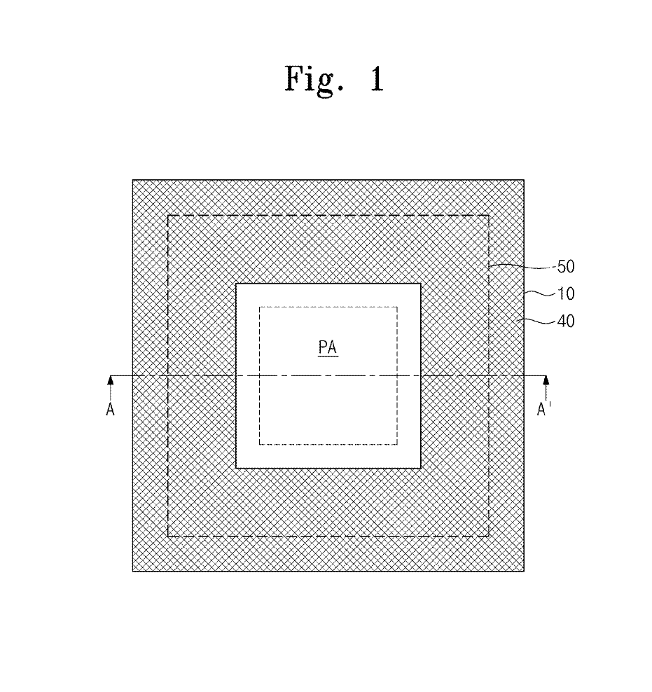

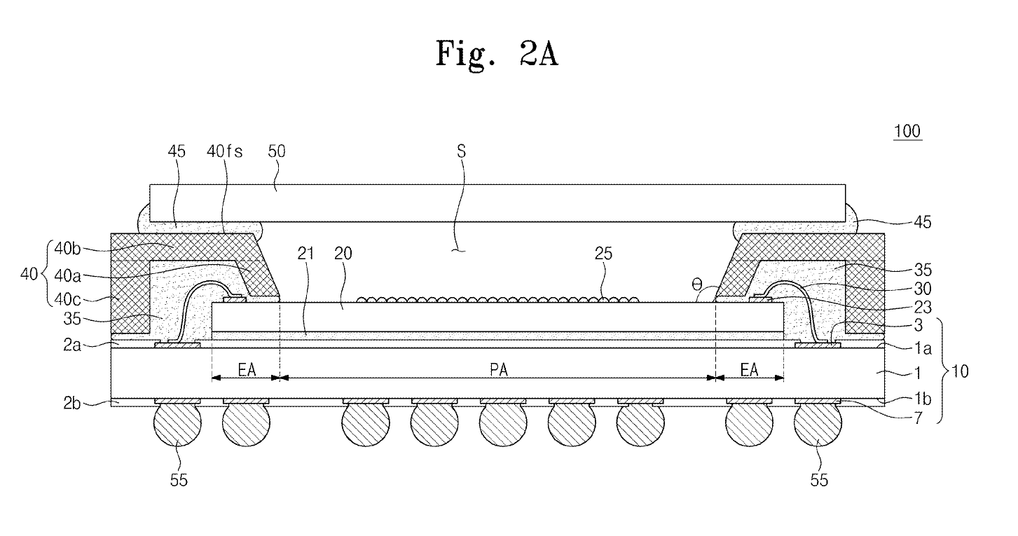

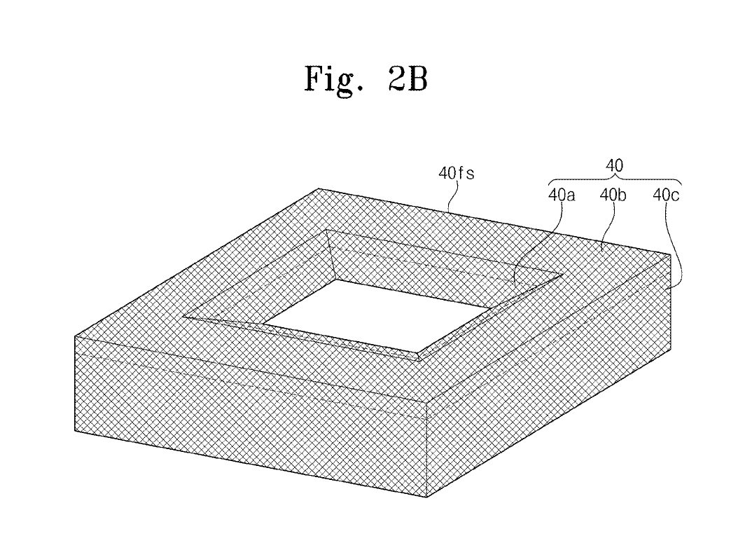

FIG. 1 is a plan view illustrating a semiconductor package according to some embodiments of the inventive concept. FIG. 2A is a cross-sectional view taken along line I-I′ of FIG. 1 to explain a semiconductor package according to a first embodiment of the inventive concept. FIG. 2B is a perspective view illustrating a holder according to a first embodiment of the inventive concept.

Referring to FIGS. 1, 2A, and 2B, a semiconductor package 100 according to the first embodiment includes a semiconductor chip 20 mounted on a package substrate 10. The package substrate 10 includes a substrate body 1, and a first surface 1a and a second surface 1b opposite to each other. The substrate body 1 may be formed of at least one of various insulating materials such as a plastic material and/or a ceramic material. A conductive via and/or one or more layers of conductive circuit patterns may be disposed within the substrate body 1. First substrate connection terminals 3 are disposed on the first surface la, and second substrate connection terminals 7 are disposed on the second surface 1b. Passivation layers 2a and 2b may cover the first surface la and the second surface 1b, respectively.

The semiconductor chip 20 may include a pixel part PA and an edge part EA. For example, the semiconductor chip 20 may be an image sensor chip. Although not shown in the drawings, a plurality of photoelectric conversion parts and a plurality of transistors may be disposed on the pixel part PA. The plurality of transistors may transmit and/or process signals transferred from the photoelectric conversion parts. A micro lens array 25 may be disposed on the pixel part PA. Peripheral circuits may be disposed on the edge part EA. Chip connection terminals 23 may be disposed on the edge part EA of the semiconductor chip 20.

In some embodiments, the edge part EA may be a portion of the semiconductor chip 20 near an edge of the semiconductor chip that may or may not include chip connection terminals 23 or peripheral circuits thereon. Also, the edge part EA may be a portion of the semiconductor chip outside of the pixel part PA. The edge part EA may substantially surround the semiconductor chip 20.

The semiconductor chip 20 may be bonded to the first surface la with a first adhesive layer 21 therebetween. For example, the first adhesive layer 21 may be a double-sided tape. In some embodiments, the semiconductor chip 20 may be mounted on the package substrate 10 by a wire bonding method. Thus, the chip connection terminal 23 may be connected to the first substrate connection terminal 3 through a wire 30.

The edge part EA of the semiconductor chip 20 may be covered by a holder 40. The holder 40 covers at least a region of the edge part EA and exposes the pixel part PA. The holder 40 has a top surface 40fs spaced apart from a top surface of the semiconductor chip 20. In more detail, the holder 40 includes an inner cover part 40a and an upper cover part 40b. The inner cover part 40a may be adjacent to the edge part EA and inclined or disposed at an angle with respect to the top surface of the semiconductor chip 20. The upper cover part 40b may be connected to a top end of the inner cover part 40a and adjacent to a transparent substrate 50. The holder 40 may further include an outer cover part 40c which is connected to the upper cover part 40b and adjacent to the package substrate 10. The inner cover part 40a, the upper cover part 40b, and the outer cover part 40c may be connected to each other to constitute one body. In other words, the inner cover part 40a, the upper cover part 40b, and the outer cover part 40c may be integrally formed into a single body. The holder 40 may have a closed loop shape in plan view. The holder 40 may be formed of a polymer material such as polyimide. An angle θ between a sidewall of the inner cover part 40a and the top surface of the semiconductor chip 20 adjacent to the pixel part PA may greater than about 90 degrees.

Thus, contaminants deposited on the sidewall of the inner cover part 40a and the top surface of the semiconductor chip 20 may be easily removed as compared with the case that the angle θ is equal to or less than 90 degrees.

The upper cover part 40b may be spaced apart from an end portion of the semiconductor chip 20 to provide a space therebetween. The space may be filled with a second adhesive layer 35. The second adhesive layer 35 may include a photosensitive adhesive polymer, a thermosetting polymer, and/or an epoxy-based mixture. The second adhesive layer 35 may be in contact with a bottom surface of the upper cover part 40b, an inner sidewall of the inner cover part 40a, and an inner sidewall of the outer cover part 40c. Additionally, the second adhesive layer 35 may be in contact with the end portion or side surface of the semiconductor chip 20 and the package substrate 10. Thus, it is possible to stably bond the holder 40 to the semiconductor chip 20 and the package substrate 10. The second adhesive layer 35 may also protect the wire 30. Additionally, the second adhesive layer 35 may protect a joint between the wire 30 and the chip connection terminal 23 and a joint between the wire 30 and the first substrate connection terminal 3. The second adhesive layer 35 may prevent joint cracks between the wire 30 and the chip connection terminal 23 and joint cracks between the wire 30 and the first substrate connection terminal 3. The second adhesive layer 35 may extend between a bottom surface of the inner cover part 40a and the top surface of the semiconductor chip 20 and between a bottom surface of the outer cover part 40c and the top surface of the package substrate 10.

Since the holder 40 covers the edge part EA of the semiconductor chip 20 to isolate the edge part EA from the pixel part PA, it is possible to substantially prevent contaminants which may exist on the edge part EA and in the holder 40 from moving to the pixel part PA. Thus, it is possible to substantially prevent distortion of an image which may be caused by such contaminants.

The transparent substrate 50 may be disposed on the upper cover part 40b, so that an empty space S is provided between the semiconductor chip 20 and transparent substrate 50. The transparent substrate 50 may be formed of a transparent glass or a transparent plastic. A third adhesive layer 45 may be disposed between an edge portion of the transparent substrate 50 and the top surface 40fs of the holder 40. The third adhesive layer 45 may include the same material as the second adhesive layer 35. The third adhesive layer 45 may extend to cover at least a portion of a sidewall of the transparent substrate 50 and at least a portion of a sidewall of the upper cover part 40b. Thus, a contact area between the third adhesive layer 45 and the transparent substrate 50 and/or a contact area between the third adhesive layer 45 and the holder 40 may become wider to improve an adhesive force therebetween.

Solder bumps or conductive bumps 55 may be bonded to the second substrate connection terminals 7, respectively.

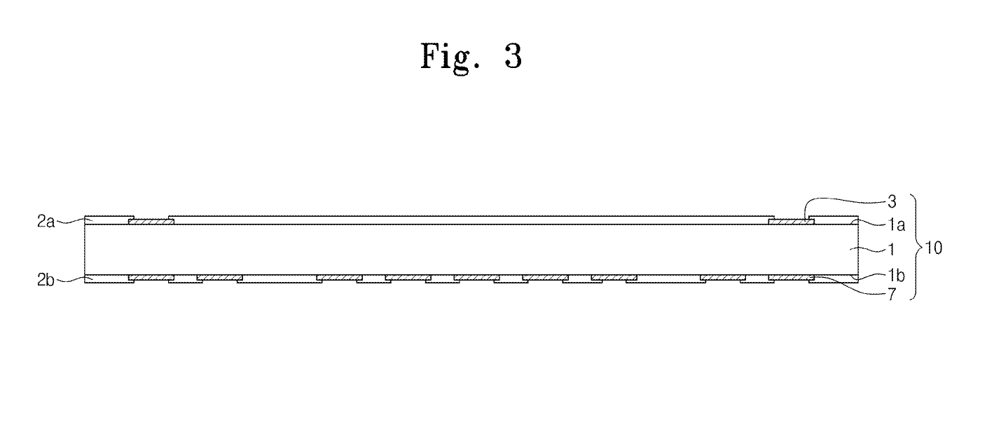

FIGS. 3 to 9 are cross-sectional views illustrating a method for manufacturing a semiconductor package of FIG. 2A.

Referring to FIG. 3, a package substrate 10 is prepared. The package substrate 10 includes a substrate body 1, and a first surface la and a second surface lb opposite to each other. The substrate body 1 may be formed of at least one of various insulating materials such as a plastic material and/or a ceramic material. A conductive via and/or one or more layers of conductive circuit patterns may be disposed within the substrate body 1. First substrate connection terminals 3 are disposed on the first surface 1 a, and second substrate connection terminals 7 are disposed on the second surface lb. Passivation layers 2a and 2b may cover the first surface 1a and the second surface lb, respectively. For example, the package substrate 10 may be a printed circuit board (PCB).

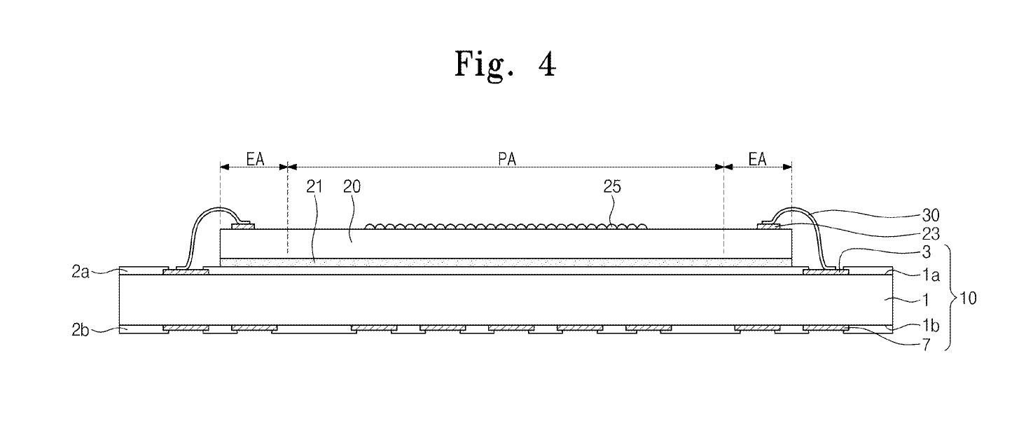

Referring to FIG. 4, a semiconductor chip 20 may be bonded on the package substrate 10 by a first adhesive layer 21. The first adhesive layer 21 may be a double-sided tape. The semiconductor chip 20 may include a pixel part PA and an edge part EA. For example, the semiconductor chip 20 may be an image sensor chip. A micro lens array 25 may be disposed on the pixel part PA. Peripheral circuits may be disposed on the edge part EA. Chip connection terminals 23 may be disposed on the edge part EA of the semiconductor chip 20. After the semiconductor chip 20 is bonded, a wire bonding method may be performed to form a wire 30 connecting the chip connection terminal 23 to the first substrate connection terminal 3.

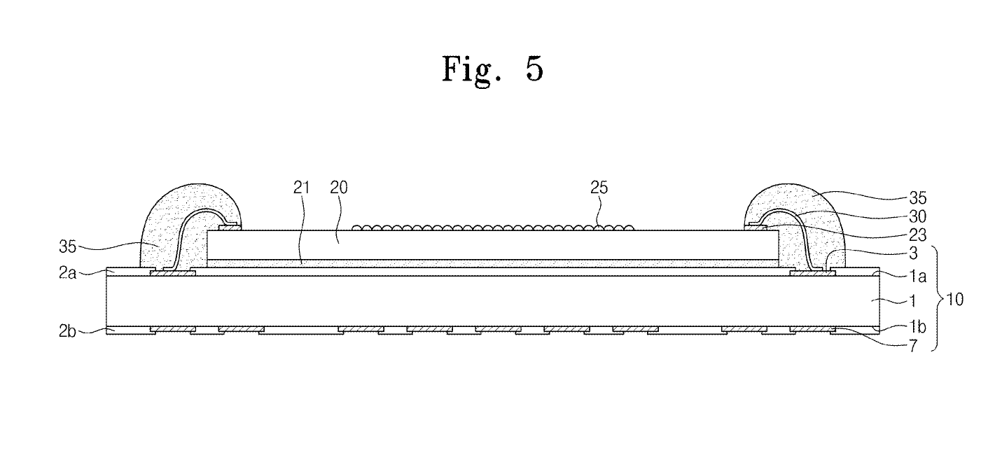

Referring to FIG. 5, a second adhesive layer 35 is formed to cover an end portion of the semiconductor chip 20 and the package substrate 10 adjacent to the end portion of the semiconductor chip 20. The second adhesive layer 35 may be supplied to the end portion of the semiconductor chip 20 and the package substrate 10 adjacent thereto by, for example, a dispensing method, a paste method, an ink-jetting method, and/or a printing method. The second adhesive layer 35 may cover the chip connection terminal 23, the wire 30, and the first substrate connection terminal 3. The second adhesive layer 35 may include a photosensitive adhesive polymer, a thermosetting polymer, and/or an epoxy-based mixture.

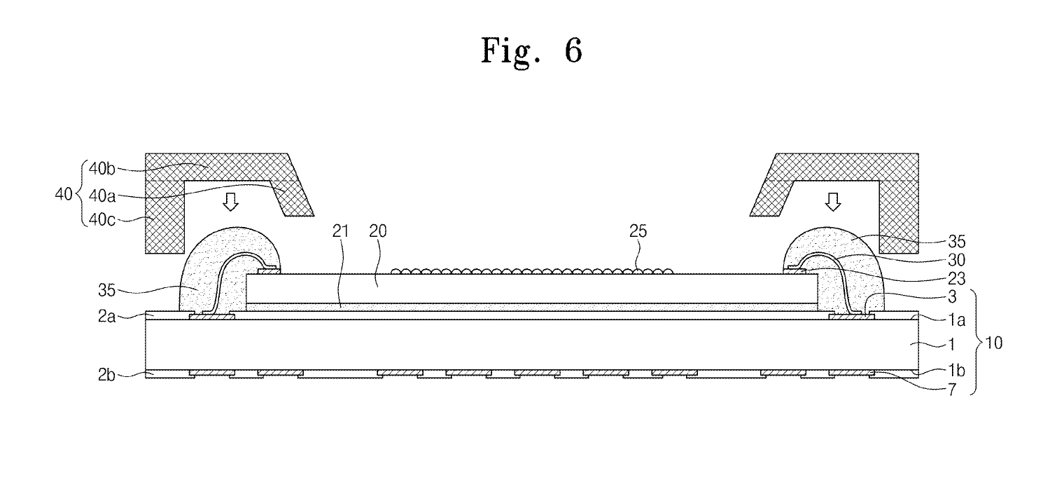

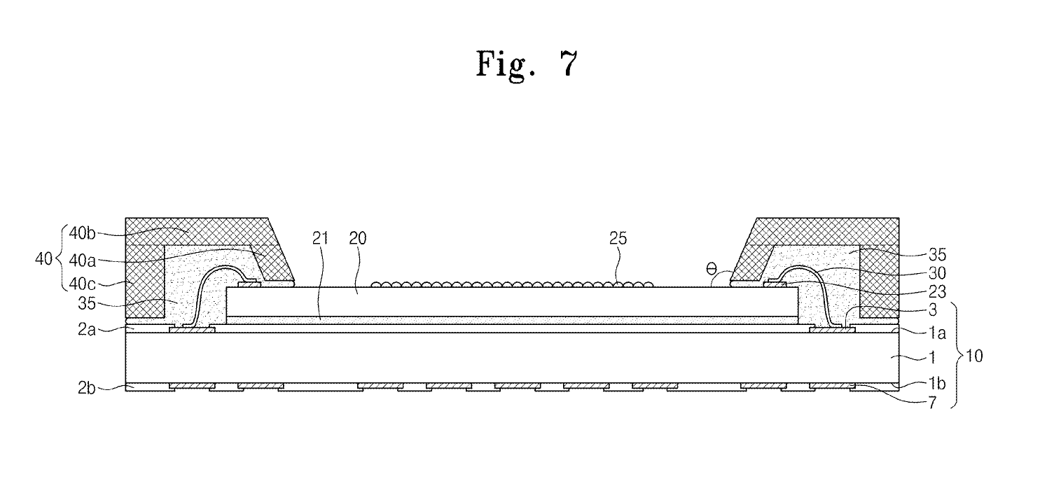

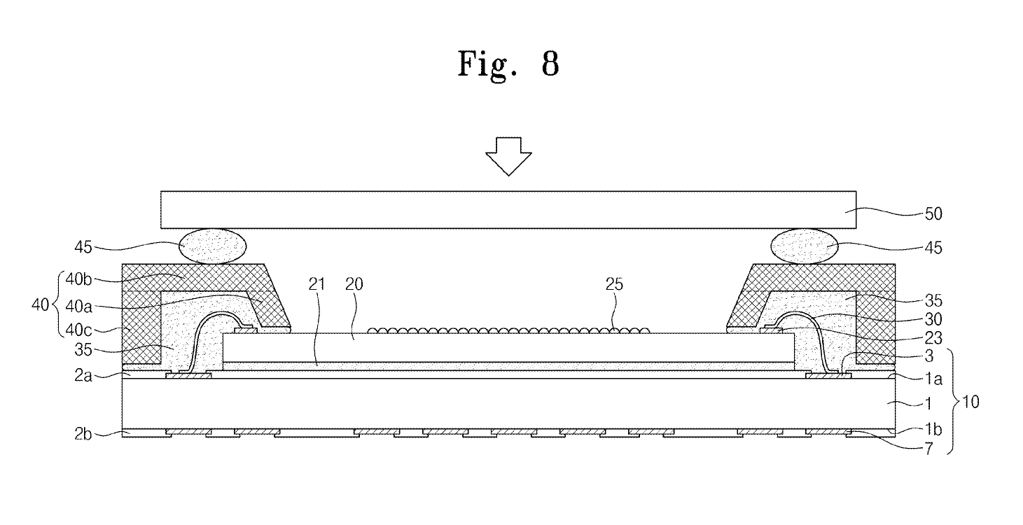

Referring to FIGS. 6 and 7, a holder 40 may be located on the package substrate 10 so as to be overlapped with the second adhesive layer 35 and then the holder 40 may be compressed. The holder 40 may include an inner cover part 40a and an upper cover part 40b. The inner cover part 40a may be adjacent to the edge part EA and inclined with respect to the top surface of the semiconductor chip 20, and the upper cover part 40b may be connected to a top end of the inner cover part 40a and adjacent to a transparent substrate 50 (FIG. 8). The holder 40 may further include an outer cover part 40c connected to the upper cover part 40b and adjacent to the package substrate 10. Thus, the second adhesive layer 35 may be pressed by the holder 40 such that it is placed in contact with a bottom surface of the upper cover part 40b, inner sidewalls of the inner cover part 40a and the outer cover part 40c. The second adhesive layer 35 may be pressed by the holder 40, such that the second adhesive layer 35 may extend between a bottom surface of the inner cover part 40a and a top surface of the semiconductor chip 20 and between a bottom surface of the outer cover part 40c and the top surface of the semiconductor chip 20.

Additionally, a process for hardening the second adhesive layer 35 may further be performed. Ultraviolet rays may be irradiated to the second adhesive layer 35 or a heating process may be performed on the second adhesive layer 35 to perform the hardening process. When the holder 40 is bonded to the semiconductor chip 20, the pixel part PA may be less impacted by the holder 40. Thus, it may be possible to substantially prevent the pixel part PA from being damaged and/or contaminated. After the holder 40 is bonded to the semiconductor chip 20, a cleaning process may be performed using a cleaning solution. At this time, the angle θ between a sidewall of the inner cover part 40a and the top surface of the semiconductor chip 20 adjacent to the pixel part PA may be greater than approximately 90 degrees as described with reference to FIG. 2A. As a result, contaminants which may be deposited or formed on the sidewall of the inner cover part 40a and the top surface of the semiconductor chip 20 may be easily removed as compared with the case that the angle θ is equal to or less than 90 degrees.

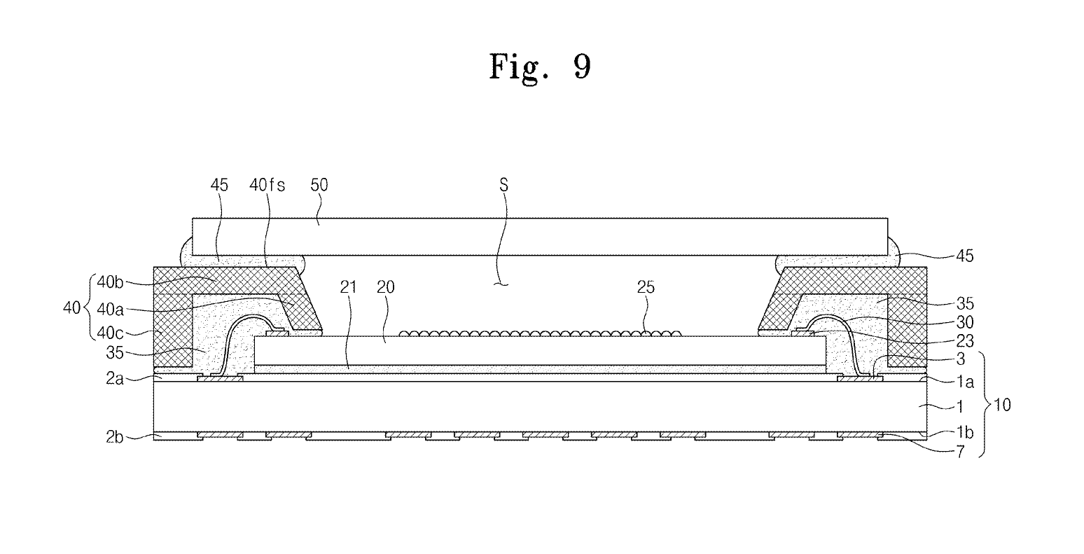

Referring to FIGS. 8 and 9, a third adhesive layer 45 may be applied to the upper cover part 40b. The third adhesive layer 45 may be formed of the same material or a similar material to that of the second adhesive layer 35 by the same method as or a similar method to the method of forming the second adhesive layer 35. After the third adhesive layer 45 is formed, an edge portion of a transparent substrate 50 is located to overlap the holder 40. The transparent substrate 50 may, for example, be formed of a transparent glass or a transparent plastic. Thereafter, the transparent substrate 50 may be pressed to compress the third adhesive layer 45. Thus, the third adhesive layer 45 may be pressed to cover at least a portion of a sidewall of the transparent substrate 50 and a portion of a sidewall of the upper cover part 40b. As a result, a contact area between the third adhesive layer 45 and the transparent substrate 50 and/or a contact area between the third adhesive layer 45 and the holder 40 may become wider to improve an adhesive force therebetween. Subsequently, a process for hardening the third adhesive layer 45 may further be performed. For hardening the third adhesive layer 45, ultraviolet rays may be irradiated to the third adhesive layer 45 or a heating process may be performed on the third adhesive layer 45.

Next, referring to FIG. 2A, solder bumps or conductive bumps 55 may be bonded to the second substrate connection terminals 7, respectively.

According to some embodiments, the holder 40 may cover the edge part EA of the semiconductor chip 20 such that the edge part EA is isolated from the pixel part PA. Thus, contaminants which may exist on the edge part EA and/or in the holder 40 may be substantially prevented from moving onto the pixel part PA. As a result, it is possible to reduce distortion of an image which may be caused by the contaminants.

### Second Embodiment

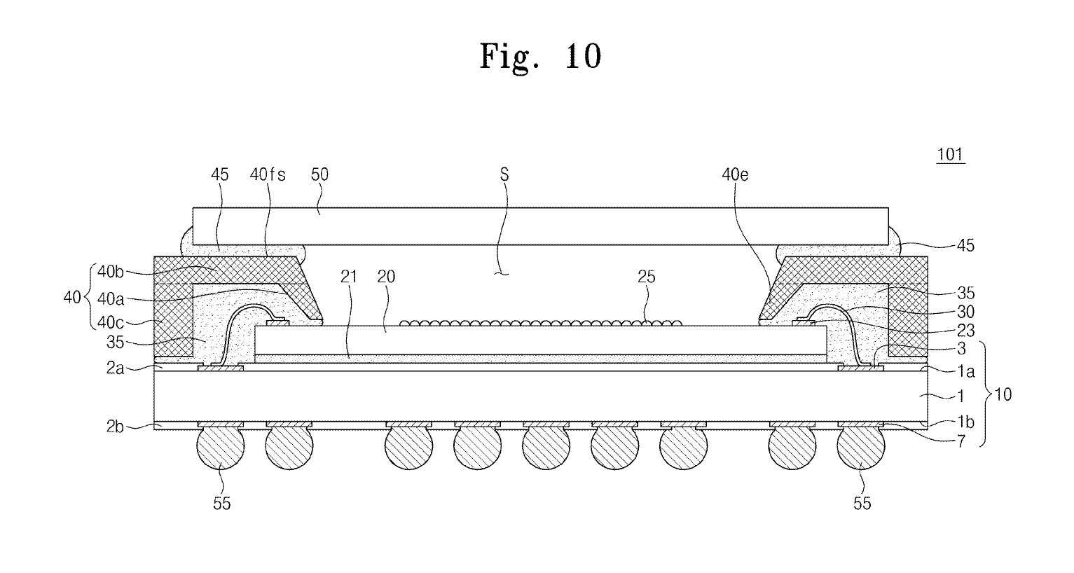

FIG. 10 is a cross-sectional view taken along line I-I′ of FIG. 1 to explain a semiconductor package according to a second embodiment of the inventive concept.

Referring to FIG. 10, in some embodiments, a width of a lower portion of the inner cover part 40a can be smaller than a width of an upper portion of the inner cover part 40a in a semiconductor package 101. Other elements of the semiconductor package 101 may be the same as/similar to corresponding elements of the semiconductor package 100 according to the first embodiment.

### Third Embodiment

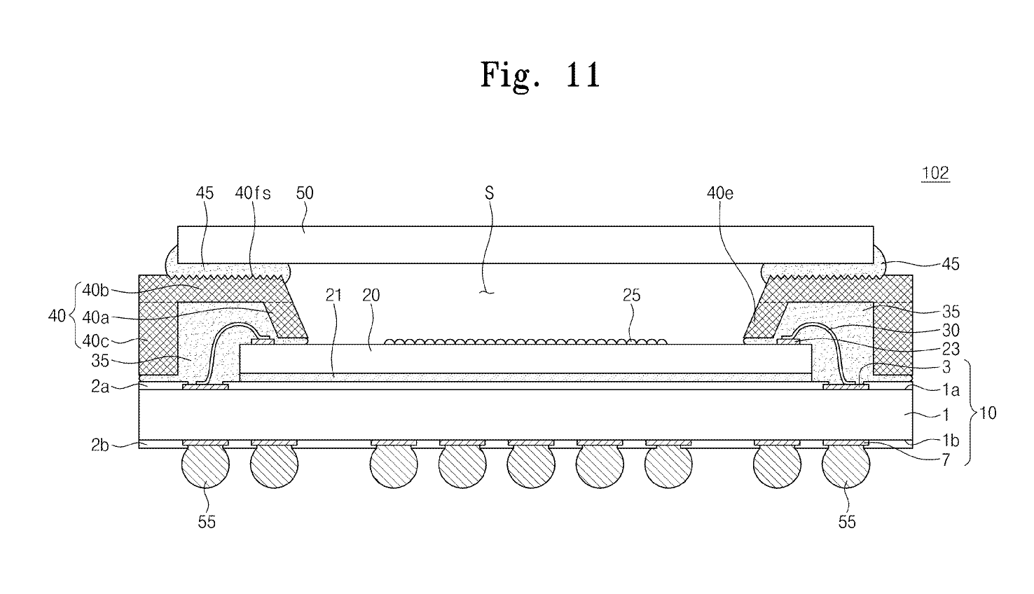

FIG. 11 is a cross-sectional view taken along line I-I′ of FIG. 1 to explain a semiconductor package according to a third embodiment of the inventive concept.

Referring to FIG. 11, according to some embodiments, a top surface 40fs of a holder 40 in a semiconductor package 102 may have increased surface roughness. More specifically, the surface roughness of the top surface 40fs of the upper cover part 40b may be greater than a surface roughness of the sidewall of the inner cover part 40a. Thus, a surface area of the top surface 40fs may become wider to increase the adhesive force of the third adhesive layer 45. Other elements of the semiconductor package 102 may be the same as/similar to corresponding elements of the semiconductor package 100 according to the first embodiment.

### Fourth Embodiment

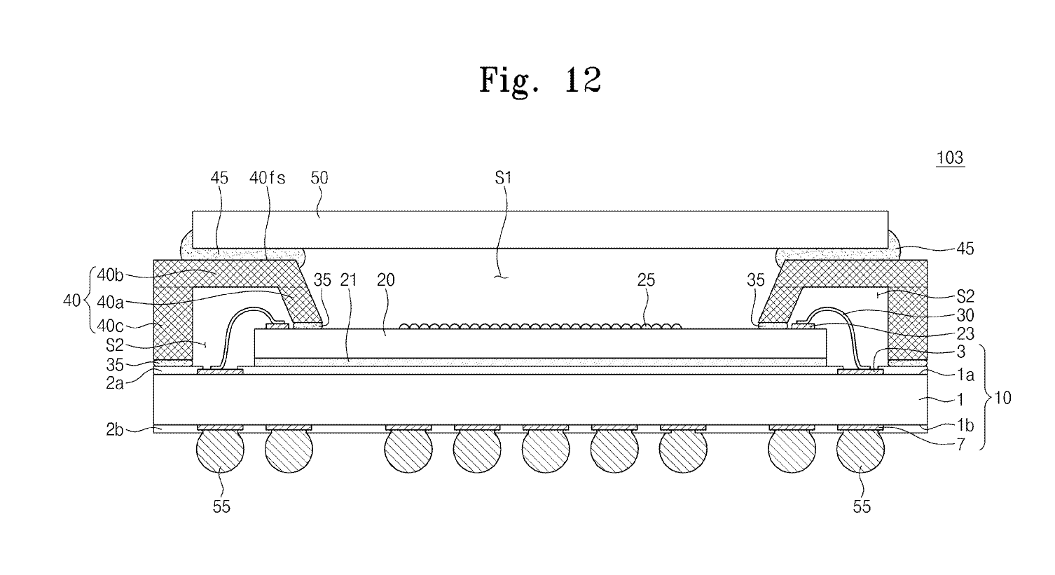

FIG. 12 is a cross-sectional view taken along line I-I′ of FIG. 1 to explain a semiconductor package according to a fourth embodiment of the inventive concept.

Referring to FIG. 12, in a semiconductor package 103 according to some embodiments, a second adhesive layer 35 may only be disposed between the bottom surface of the inner cover part 40a and the semiconductor chip 20 and between the bottom surface of the outer cover part 40c and the package substrate 10. Thus, a first empty space Si may be defined between the transparent substrate 50 and the semiconductor chip 20, and a second empty space S2 may be defined between the holder 40 and the end portion of the semiconductor chip 20. Other elements of the semiconductor package 103 may be the same as/similar to corresponding elements of the semiconductor package 100 according to the first embodiment.

### Fifth Embodiment

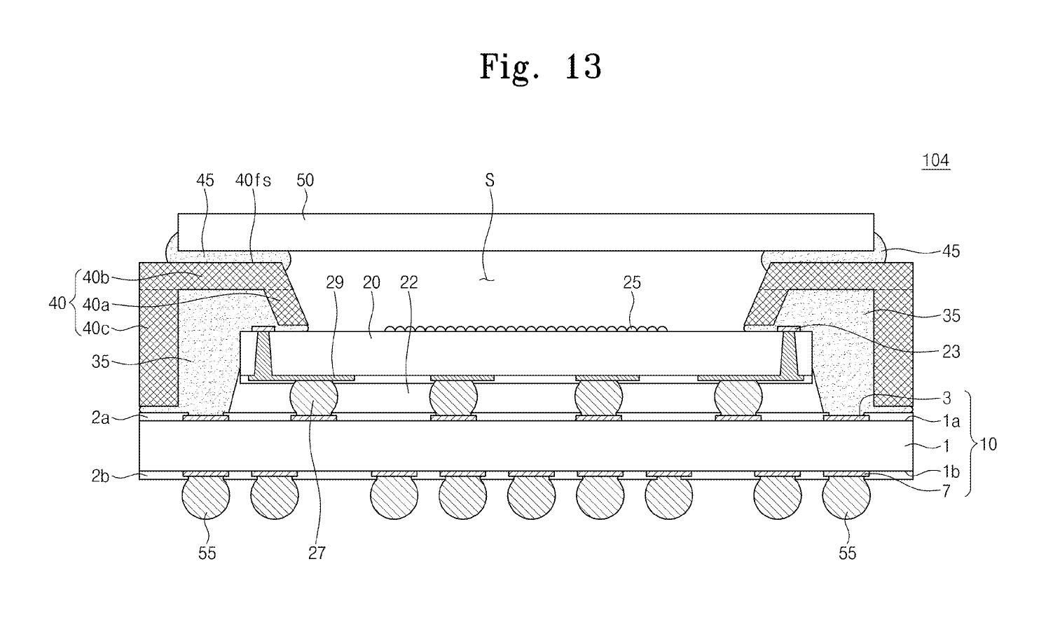

FIG. 13 is a cross-sectional view taken along line I-I′ of FIG. 1 to explain a semiconductor package according to a fifth embodiment of the inventive concept.

Referring to FIG. 13, a semiconductor chip 20 may be mounted on the package substrate 10 by, for example, a flip-chip bonding method in a semiconductor package 104 according to some embodiments. The semiconductor chip 20 may include through-vias 29. The through-via 29 may extend through the semiconductor chip 20 and be connected to the chip connection terminal 23. Inner solder bumps or inner conductive bumps 27 may be disposed between the semiconductor chip 20 and the package substrate 10. The inner solder bump 27 electrically connects the through via 29 to the first substrate connection terminal 3. An underfill resin layer 22 may be disposed between the semiconductor chip 20 and the package substrate 10. The semiconductor package 104 may not include the wire 30 described in the first embodiment.

Other elements of the semiconductor package 104 may be the same as/similar to corresponding elements of the semiconductor package 100 according to the first embodiment.

### Sixth Embodiment

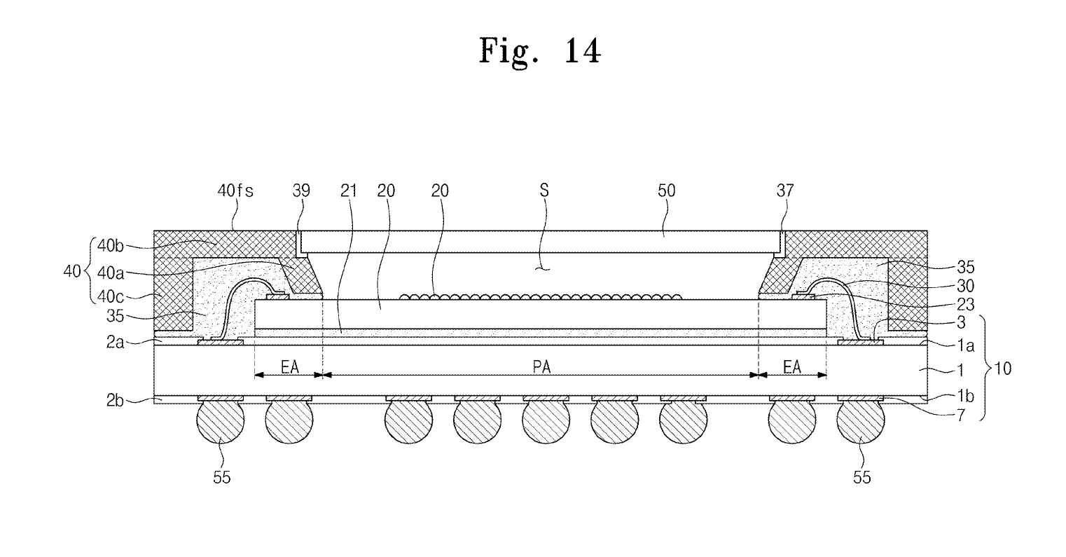

FIG. 14 is a cross-sectional view taken along line I-I′ of FIG. 1 to illustrate a semiconductor package according to a sixth embodiment of the inventive concept. In some embodiments, a transparent substrate 50 may be disposed within recesses 37 formed in a portion of the holder 40, e.g., sidewalls of the inner cover part 40a, such that end portions of the transparent substrate 50 may be disposed within the recesses 37 to fix the transparent substrate 50 to the holder 40. Therefore, the overall thickness of the semiconductor package can be substantially reduced. A fourth adhesive layer 39 may be optionally formed on the recesses 37 before the end portions of the transparent substrate 50 are fixed within the recesses 37 to provide secure coupling of the transparent substrate 50 to the holder 40. In some embodiments, the fourth adhesive layer 39 may be omitted.

In some embodiments, the top surface 40fs of the upper cover part 40b may be substantially coplanar with the top surface of the transparent substrate 50. Other elements of the semiconductor package 101 may be the same as/similar to corresponding elements of the semiconductor package 100 according to the first embodiment.

[Application Examples]

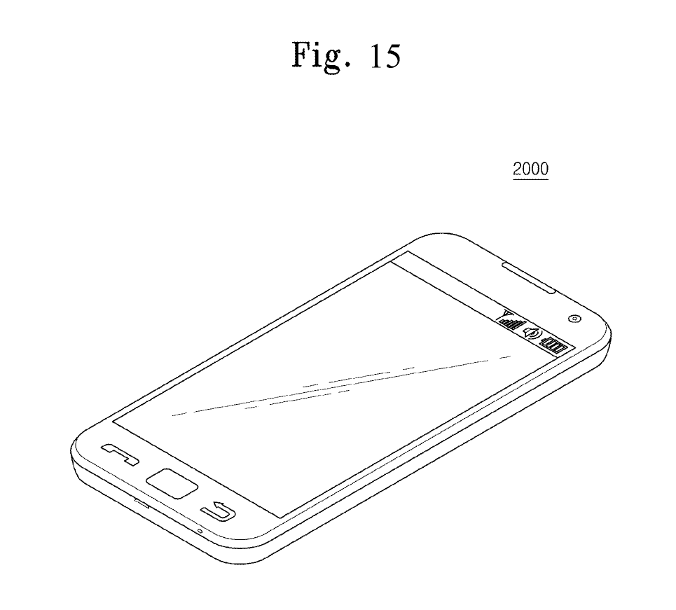

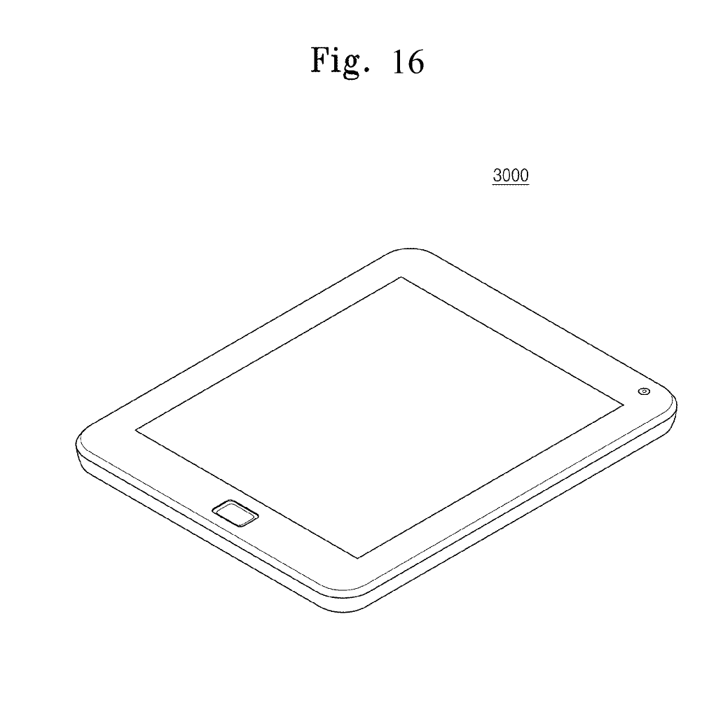

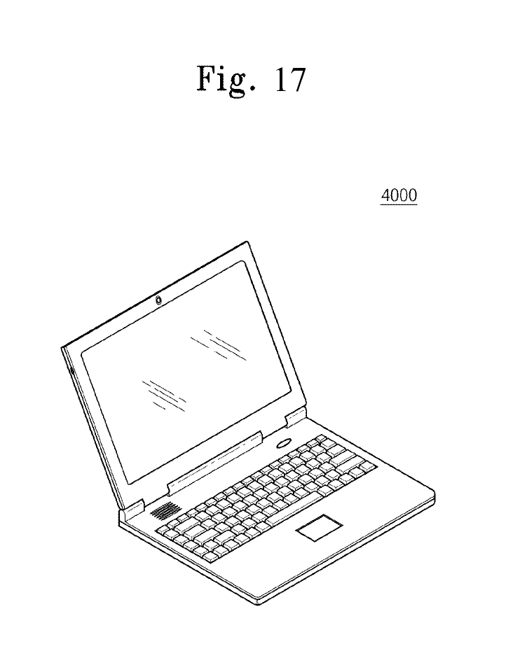

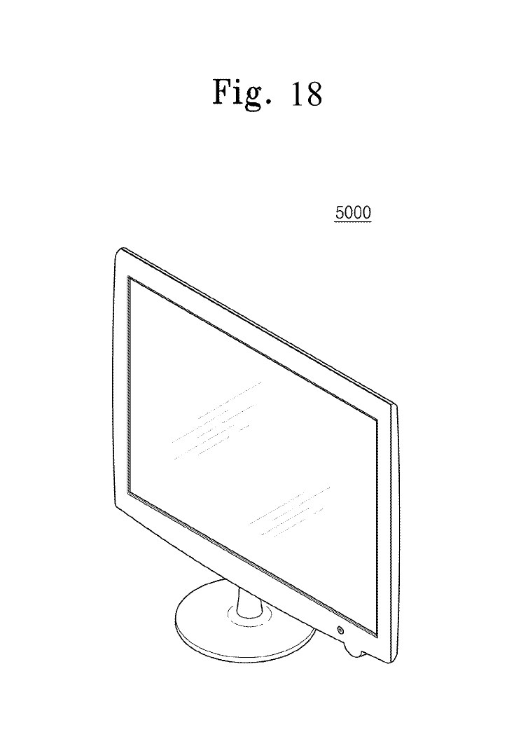

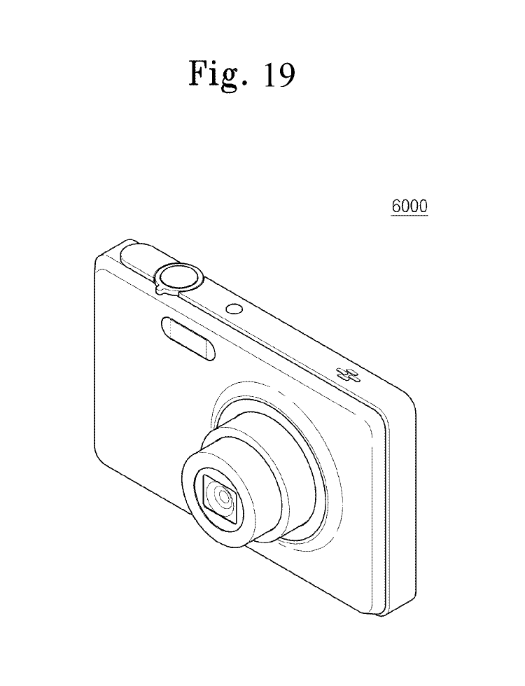

FIGS. 15 to 19 show examples of multimedia devices employing semiconductor packages for photographing an image according to some embodiments of the inventive concept. The semiconductor package 100, 101, 102, 103, or 104 for photographing an image according to some embodiments of the inventive concept may be employed to manufacture various multimedia devices having an image photographing function. For example, the semiconductor package 100, 101, 102, 103, or 104 according to some embodiments of the inventive concept may be employed to manufacture a mobile or smart phone 2000 as illustrated in FIG. 15, or be employed to manufacture a tablet or a smart tablet 3000 as illustrated in FIG. 16. In some other embodiments, the semiconductor package 100, 101, 102, 103, or 104 may be employed to manufacture a notebook computer 4000 as illustrated in FIG. 17. In still other embodiments, the semiconductor package 100, 101, 102, 103, or 104 may be employed to manufacture a television or a smart television 5000 as illustrated in FIG. 18. In yet other embodiments, the semiconductor package 100, 101, 102, 103, or 104 may be employed to manufacture a digital camera or a digital camcorder 6000 as illustrated in FIG. 19.

Since the semiconductor package according to embodiments of the inventive concept includes the holder covering the edge part of the semiconductor chip, it is possible to isolate the edge part on which the contaminants may easily exist from the pixel part. As a result, the contaminants of the edge part do not contaminate the pixel part, so that the distortion of the image may be prevented.

In the method for manufacturing the semiconductor package according to some embodiments of the inventive concept, the sidewall of the inner cover part is inclined with respect to the top surface of the pixel part by the angle greater than about 90 degrees. Thus, the cleaning process may be more easily performed. As a result, it is possible to easily remove the contaminants existing between the inner cover part and the top surface of the semiconductor chip.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A semiconductor package comprising:
a package substrate including an insulating material;
a semiconductor chip disposed on the package substrate and including a pixel part and an edge part arranged outside of the pixel part;
a holder covering at least a region of the edge part and exposing the pixel part; and
a transparent substrate disposed adjacent to the top surface of the holder.

2. The semiconductor package of claim 1, wherein the holder includes an inner cover part and an upper cover part;
wherein the inner cover part is adjacent to the edge part and is inclined with respect to a top surface of the semiconductor chip; and
wherein the upper cover part is connected to a top end of the inner cover part and is adjacent to the transparent substrate.

3. The semiconductor package of claim 2, wherein the holder further includes an outer cover part connected to the upper cover part and adjacent to the package substrate.

4. The semiconductor package of claim 3, further comprising:
an adhesive layer disposed between the outer cover part and the package substrate or between the inner cover part and the semiconductor chip, or both.

5. The semiconductor package of claim 2, wherein an angle between a sidewall of the inner cover part and the top surface of the semiconductor chip adjacent to the pixel part is greater than about 90 degrees.

6. The semiconductor package of claim 2, wherein the upper cover part is spaced apart from an end portion of the semiconductor chip to provide a space therebetween.

7. The semiconductor package of claim 6, further comprising:
a first adhesive layer filling the space.

8. The semiconductor package of claim 7, wherein the first adhesive layer extends between a bottom surface of the inner cover part and the top surface of the semiconductor chip.

9. The semiconductor package of claim 7, further comprising:
a second adhesive layer disposed between an end portion of the transparent substrate and the upper cover part.

10. The semiconductor package of claim 9, wherein the second adhesive layer covers at least a portion of a sidewall of the transparent substrate or at least a portion of a sidewall of the upper cover part.

11. The semiconductor package of claim 2, wherein a surface roughness of a top surface of the upper cover part is greater than a surface roughness of a sidewall of the inner cover part.

12. The semiconductor package of claim 2, wherein a width of a lower portion of the inner cover part is smaller than a width of an upper portion of the inner cover part.

13. The semiconductor package of claim 1, further comprising:
a wire connecting the edge part to the package substrate,
wherein the holder covers the wire.

14. The semiconductor package of claim 1, wherein the semiconductor chip is flip-chip bonded to the package substrate.

15. A semiconductor package comprising:
a package substrate;
a semiconductor chip overlying the package substrate, the semiconductor chip including a pixel part and an edge part outside of the pixel part;
a holder having a portion covering at least a region of the edge part, the pixel part being exposed through the holder;
an adhesive layer arranged between the holder and the edge part; and
a transparent substrate disposed adjacent to the top surface of the holder.

16. The package of claim 15, wherein a chip connection terminal formed on the edge part of the semiconductor chip is disposed within the portion covering the edge part.

17. The package of claim 15, further comprising through-vias extending through the semiconductor chip, the through-vias coupled to the chip connection terminals.

18. The package of claim 15, wherein the portion covering the edge part is bonded to a portion of the edge part outside of the pixel part via the adhesive layer.

19. The package of claim 15, further comprising conductive bumps bonded to a bottom surface of the package substrate.

20. (canceled)

21. (canceled)
